(19) United States
(12) Patent Application Publication
(10) Pub. No.: US 2003/0042929 A1
(43) Pub. Date: Mar. 6, 2003

(54) Driver circuit

(76) Inventors: Ernst Josef Kock, Kirchseeon (DE); Peter Rohm, Pfaffenhofen (DE)

Correspondence Address: LERNER AND GREENBERG, P.A., Post Office Box 2480, Hollywood, FL, 33022-2480, US

(21) Appl. No.: 10/233,699

(22) Filed: Sep. 3, 2002

(30) Foreign Application Priority Data
Aug. 31, 2001 (DE) 101 42 679.8

(51) Int. Cl. H03K 19/0175

(52) U.S. Cl. 326/31

(57) ABSTRACT

A driver circuit includes a driver and a control device that controls the driver. The control device modifies the power of the driver based on the waveform of the signal (DAT_OUT) to be driven by the driver and/or based on the waveform of the signal output by the driver. Such a driver circuit makes it possible to reduce the energy consumption of the driver and/or the interference caused by the driver to a minimum.

### BACKGROUND OF THE INVENTION

1. Field of the Invention

The present invention relates to driver circuits that include drivers and control devices that control the drivers.

A driver is a circuit that uses a signal fed to it to generate a signal that is identical but suitable for driving higher loads, and outputs the signal.

Mentioning only one of a virtually unlimited number of possible uses, drivers are used for example in microcontrollers in order to output from the microcontroller data generated within the microcontroller. However, drivers are also used in virtually all other existing integrated circuits.

Drivers have been known for many years in innumerable embodiments, so that it is possible to dispense with further explanations relating to their construction and function.

It is also known to control the drivers by using control devices. In this case, in particular, the power of the driver is matched to the given conditions. By matching the driver to the given conditions, the current consumption of the driver and the electromagnetic interference generated by the driver can be reduced.

However, experience shows that the current consumption of the drivers and the electromagnetic interference caused by them are still relatively high even when the drivers are matched to the given conditions by control devices.

### SUMMARY OF THE INVENTION

It is accordingly an object of the invention to provide a driver circuit that overcomes the above-mentioned disadvantages of the heretofore-known devices of this general type and that includes a driver and a control device that controls the driver in such a way that the current consumption of the driver and the electromagnetic interference caused by the driver can be reduced further.

With the foregoing and other objects in view there is provided, in accordance with the invention, the control device that modifies the power of the driver based on the waveform of the signal to be driven by the driver and/or based on the waveform of the signal output by the driver.

This makes the following possible. In phases in which the signal to be driven and/or the signal output by the driver does not change its value, will not change its value or cannot change its value, the driver is put into a state in which it has a low driver power. In addition, in phases in which the signal to be driven and/or the signal output by the driver changes its value, will change its value or can change its value, the driver is put into a state in which it has a higher driver power.

A driver driven in this way uses no more energy and produces no more interference than is unavoidable under the given circumstances.

Other features that are considered as characteristic for the invention are set forth in the appended claims.

Although the invention is illustrated and described herein as embodied in a driver circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram showing a first exemplary embodiment of the driver circuit according to the invention;

FIG. 2 is a block diagram showing the driver circuit in more detail;

FIG. 3 is a block diagram showing a configuration for stepwise increasing/decreasing of the driver power; and

FIG. 4 is a block diagram showing a third exemplary embodiment of the driver circuit.

### DESCRIPTION OF THE PREFERRED EMBODIMENTS

The driver circuits described in the following text are a constituent part of a microcontroller, but can also be a constituent part of another program-controlled unit, such as a microprocessor or a signal processor, for example. They can also be a constituent part of any other desired integrated circuit, or non-integrated circuit.

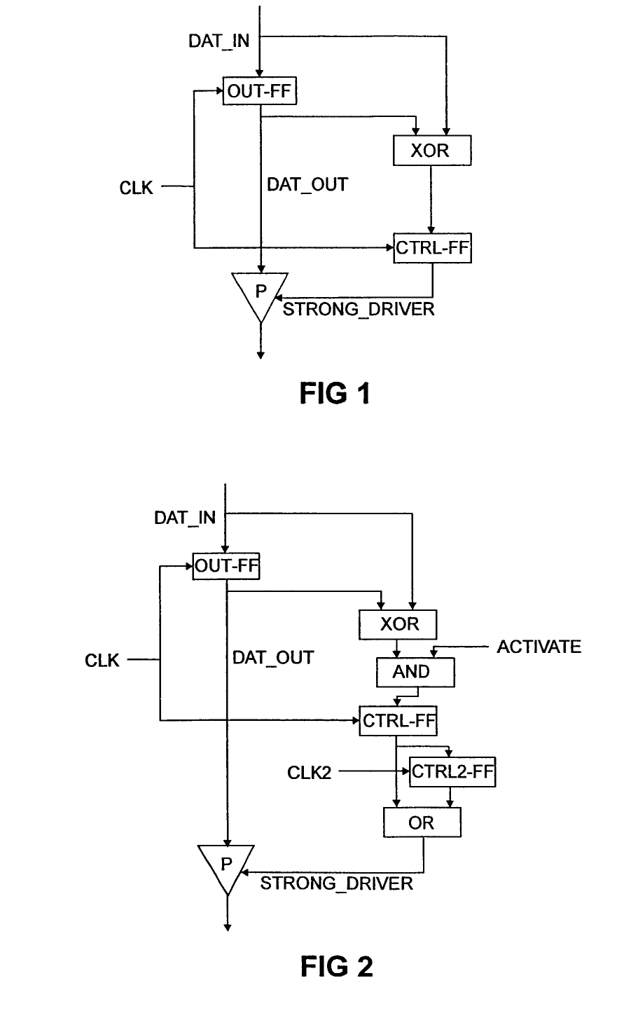

Referring now to the figures of the drawing in detail and first, particularly, to FIG. 1 thereof, it is seen that the type of driver circuits considered in the present case contains a driver P, a first flip-flop OUT-FF, an XOR gate XOR, and a second flip-flop CTRL-FF.

The core of the driver circuit shown is the driver P. The driver P is supplied by the first flip-flop OUT-FF with a signal designated by DAT_OUT in FIG. 1. The driver P produces a signal that is identical but suitable for driving higher loads and outputs said signal. The remaining components of the driver circuit, that is to say the XOR gate XOR, and the second flip-flop CTRL-FF, form a control device that controls the driver P, more precisely its power, based on the waveform of the signal DAT_OUT supplied to the driver.

A digital input signal DAT_IN is supplied to the first flip-flop FF-OUT, is accepted by the first flip-flop FF-OUT on the rising or the falling edge of a clock signal CLK, and is output to the driver P as the signal DAT_OUT already mentioned. The signals DAT_IN and DAT_OUT are also supplied to the XOR gate XOR as input signals. The XOR gate subjects the signals supplied to it to XOR linking and outputs the result to the second flip-flop CTRL-FF. The second flip-flop accepts the signal supplied to it by the XOR gate XOR on the rising or the falling edge of the clock signal CLK and passes it on to the driver P as a signal STRONG_DRIVER that controls the driver P.

If and as long as the signal STRONG_DRIVER has the value 0, which is the case when the signals DAT_IN and DAT_OUT had the same value in the preceding clock signal period, the driver P is set by the signal STRONG_DRIVER into a state in which it has a low driver power. If and as long as the signal STRONG_DRIVER has the value 1, which is the case when the signals DAT_IN and DAT_OUT had different values in the preceding clock signal period, the driver P is set by the signal STRONG_DRIVER into a state in which it has a high driver power.

This has the following effect. The driver P, at the same time as the arrival of a change in the level of the signal supplied to it, is set into a state in which it has a high driver power. The driver P is kept in this state for a clock signal period. The driver P is kept in the state in which it has a high driver power for a further clock signal period or when a further change follows immediately after the change in the level of the signal supplied to it. Or, the driver P is again set into a state in which it has a low driver power and is kept in this state until there is again a change in the level of the signal supplied to it and to be output by it when a further change does not follow immediately following the change in level of the signal supplied to it and to be output by it.

Changes in the level of the signal supplied to the driver P and to be output by it are both changes from the low level to the high level and changes from the high level to the low level.

Changing the driver P over from the low driver power to the high driver power can be carried out, for example, by an additional driver transistor in the driver P being activated. This changes the driver P over from the high driver power to the low driver power can be carried out, for example, by the additional driver transistor being deactivated again.

The high driver power is dimensioned such that the signal output by the driver P, in particular the edges contained therein, exhibits a time profile as desired.

The fact that the driver P has the high driver power only when the signal to be output by it changes its level does not have any disadvantageous effects on the function of the driver. This is because high driver powers are needed only during level changes; at all other times, the driver manages with considerably lower driver powers.

The fact that the driver P is automatically set into a state in which it has a low driver power whenever no high driver power is required reduces the energy consumption of the driver circuit.

FIG. 2 shows a driver circuit modified in some points. The driver circuit shown in FIG. 2 contains a driver P, a first flip-flop OUT-FF, an XOR gate XOR, an AND gate AND, a second flip-flop CTRL-FF, a third flip-flop CTRL2-FF, and an OR gate OR.

The core of the driver circuit shown is again the driver P. The latter is fed by the first flip-flop OUT-FF a signal designated by DAT_OUT in FIG. 2, produces from this a signal that is identical but suitable for driving greater loads and outputs said signal. The remaining components of the driver circuit, that is to say the XOR gate XOR, the AND gate AND, the second flip-flop CTRL-FF, the third flip-flop CTRL2-FF, and the OR gate OR, form a control device which controls the driver P, more precisely its power, depending on the waveform of the signal DAT_OUT supplied to it.

The first flip-flop FF-OUT is supplied with a digital input signal DAT_IN, which is accepted by the first flip-flop FF-OUT on the rising or the falling edge of a first clock signal CLK and is output to the driver P as the signal DAT_OUT already mentioned. The signals DAT_IN and DAT_OUT are also supplied to the XOR gate XOR as input signals. The XOR gate subjects the signals supplied to it to XOR linking and outputs the result to the AND gate AND. The AND gate AND is supplied with a signal ACTIVATE as a second input signal. By using the AND gate, the modification of the driver power can be activated (ACTIVATE=1) or deactivated (ACTIVATE=0). The AND gate AND subjects the signals supplied to it to AND linking and outputs the result to the second flip-flop CTRL-FF. The second flip-flop CTRL-FF accepts the signal supplied to it by the AND gate AND on the rising or the falling edge of the first clock signal CLK and forwards the result to the OR gate OR and the third flip-flop CTRL2-FF. The third flip-flop CTRL2-FF accepts the signal supplied to it by the first flip-flop CTRL-FF on the rising or the falling edge of a second clock signal CLK2 and forwards it to the OR gate OR. The OR gate OR subjects the signals supplied to it to OR linking and outputs the result to the driver P as a signal STRONG_DRIVER that controls the driver P.

As can be seen from the preceding explanations, the driver circuit according to FIG. 1 and the driver circuit according to FIG. 2 agree to a great extent; the components and signals of the driver circuits according to FIG. 1 and FIG. 2 which are designated by the same reference symbols are identical or mutually corresponding components or signals. However, the driver circuit according to FIG. 2 additionally includes the AND guide AND, the third flip-flop CTRL2-FF, the OR gate OR, the signal ACTIVATE, and the second clock signal CLK2. The AND gate AND and the signal ACTIVATE permit the activation (ACTIVATE=1) and deactivation (ACTIVATE=0) of the control device that controls the driver P. In addition, the effect of the third flip-flop CTRL2-FF, the OR gate OR, and the second clock signal CLK2 is that the time at which the driver is reset from a state in which it has a high driver power into a state in which it has a low driver power again is displaced back, more precisely, is displaced back by up to one clock period of the second clock signal CLK2 based on the phase angle of the second clock signal CLK2 with respect to the first clock signal CLK. This has the positive effect that no spikes can form on the signal STRONG_DRIVER that controls the driver P.

The function of the driver circuit according to FIG. 2 otherwise corresponds to the function of the driver circuit according to FIG. 1.

The same effects would be established if the third flip-flop CTRL2-FF were to be replaced by a shift register, which accepts the signal obtained from the second flip-flop CTRL-FF at the clock rate of the second clock signal CLK2 and shifts it onward, and whose elements output the respective current content of said signal to the OR gate OR.

In the driver circuits described with reference to FIGS. 1 and 2, the driver P is set into a state in which it has a high driver power at the same time as the start of a change in the signal to be driven. After the change in the value of the signal to be driven has been completed, the driver P is reset into a state in which it has a low driver power.

An appropriate modification of the driver circuits enables the driver P to be set into a state in which it has a high driver power even before the time at which the signal to be driven begins to change or only after the time at which the signal to be driven begins to change.

Irrespective of this, an appropriate modification of the driver circuit also can be made to reset the driver into a state in which it has a low driver power precisely when the change in the value of the signal to be driven has just been completed, or that resetting the driver into a state in which it has a low driver power is carried out before the change in the value of the signal to be driven has been completed.

The aforementioned modifications of the driver circuits can be embodied, for example, in a different clock signal (a clock signal with a different clock frequency and/or with a different phase angle) being used for the second flip-flop CTRL-FF than that for the first flip-flop OUT-FF.

It also proves to be particularly beneficial if the driver P is driven in such a way that it is set into a state having a high driver power only after the time at which the signal to be driven begins to change. Furthermore, the driver P should be reset into a state in which it has a low driver power even before the time at which the change in the value of the signal to be driven has been completed.

This has the positive effect that the signal output by the driver P follows slowly the change in the signal to be driven at the start of a change in the signal to be driven because the driver power then is still low. The signal output then follows quickly the change in the signal to be driven because the driver power has been raised. Finally, the driver signal follows slowly the change in the signal to be driven because of the driver power then is low again at the end of the change in the signal to be driven. As a result, the signal output by the driver P does not exhibit any abrupt changes, and no or only slight electromagnetic interference or dips in the supply voltage are produced.

In general terms, it also proves to be advantageous if, in addition, or alternatively, the increase and/or the reduction in the driver power is carried out continuously or in a plurality of steps.

In the driver circuit shown in FIG. 1, this may be implemented, for example, by the second flip-flop CTRL-FF being replaced by a shift register that is clocked quickly. The shift register accepts the signals obtained from the XOR gate XOR at the clock rate of a clock signal with a higher frequency than CLK and shifts the signals onward. The elements of the shift register output the respective current content of the same to the driver P as control signals for controlling the same. Each of these control signals can activate and deactivate a dedicated driver transistor within the driver P.

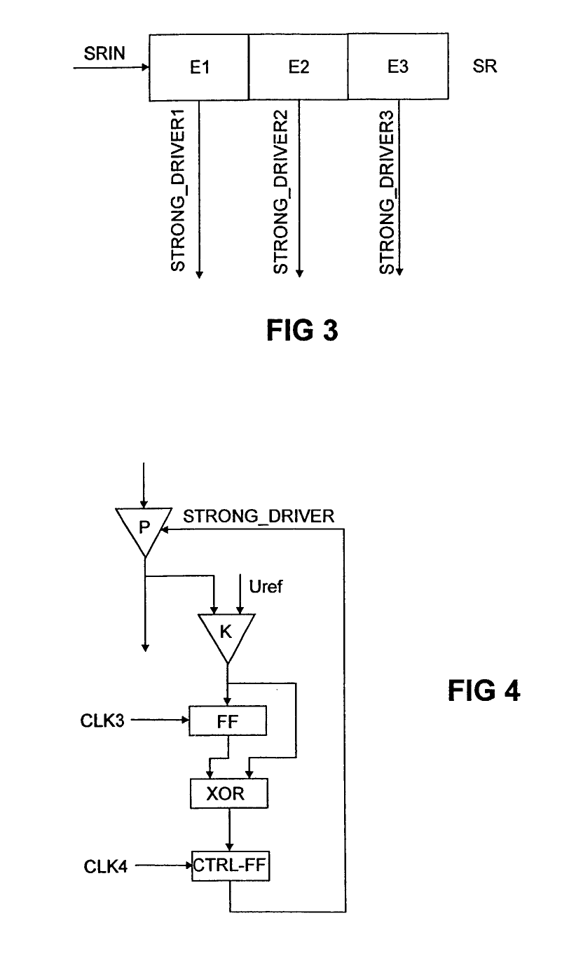

Such a shift register is illustrated by way of example in FIG. 3. Here, SR designates the shift register, E1 to E3 the shift register elements, SRIN the input signal supplied to the shift register SR by the XOR gate, and STRONG_DRIVER 1 to STRONG_DRIVER 3 the control signals produced by the shift register to control the driver.

In the driver circuits described above, the signal to be driven by the driver P was the output signal from a flip-flop, more precisely the output signal from the flip-flop OUT-FF. However, control of the driver P, carried out as described, can also be carried out if this is not the case, that is, if the signal to be driven is, for example, the output signal from combinational logic or other device connected upstream of the driver. In this case, based on a change in the input signals of the device connected upstream of the driver and/or based on the value of an enable signal which activates or deactivates the driver P and/or the device connected upstream of the latter, it can be determined whether a signal is to be driven at all and whether the signal to be driven will change or can change, and the driver power of the driver P can be varied on this basis.

Controlling the driver could also be made a function of the waveform of the output signal from the driver P. This could be done, for example, by the output signal from the driver P being supplied to a comparator. The comparator outputs the signal 1 when the signal output by the driver P exceeds a first threshold value lying close to the potential representing the level 0. Furthermore, the comparator outputs the signal 0 when the signal output by the driver P falls below a second threshold value lying close to the potential representing the level 1. In addition, the output signal from the comparator is supplied to a flip-flop. Then a comparison between the input signal and the output signal of the flip-flop is used to determine whether the output signal of the driver is just changing, the evaluation of the input signal and of the output signal of the flip-flop being carried out like the evaluation of the input signal and of the output signal from the second flip-flop OUT-FF of the driver circuit according to FIG. 1, that is to say by using an XOR gate and a second flip-flop.

Such a driver circuit is shown in FIG. 4. Reference symbol P designates the driver, K the comparator, FF the first flip-flop, XOR the XOR gate, and CTRL-FF the second flip-flop.

In the same way as changes in the output signal from the driver are detected and treated, changes in the input signal of the driver can also be detected and treated.

Determining whether the signal to be driven and/or the signal output by the driver changes can also be carried out by applying a combination of the measures described above.

The driver circuits described make it possible, irrespective of the details of the practical implementation, to drive the driver contained therein in such a way that its power consumption and/or the interference caused by it can be reduced to a minimum. The implementation of the control device that controls the driver by using a digital circuit further makes it possible to reliably prevent the occurrence of glitches or spikes in the signal that controls the driver, and to test the control device quickly and simply.

We claim:

1. A driver circuit, comprising:
a driver for outputting a signal having a waveform, said waveform having a power; and
a control device connected to said driver for controlling said driver and modifying the power of said driver based on the waveform of the signal.

2. The driver circuit according to claim 1, wherein said driver drives the signal.

3. The driver circuit according to claim 2, wherein the signal to be driven is a digital signal.

4. The driver circuit according to claim 1, wherein said control device is at least partly a digital circuit.

5. The driver circuit according to claim 1, wherein said control device is an at least partly clock-controlled circuit.

6. The driver circuit according to claim 1, wherein said control device checks if the signal to be output by said driver has a changeable value and then modifies the power of the driver.

7. The driver circuit according to claim 6, further comprising:
a flip-flop receiving the signal as an input signal and outputting the signal as an output signal;
said control device assuming the signal to be changeable when the input signal and the output signal from said flip-flop differ.

8. The driver circuit according to claim 6, further comprising:
a device connected upstream of said driver and relaying an input signal to said driver;
said control device assuming the signal to be changeable if the input signal changes.

9. The driver circuit according to claim 6, further comprising:
a device connected upstream of said driver and being activatable and deactivatable by an enable signal;
said driver being activatable and deactivatable by the enable signal; and
said control device assuming the signal to be changeable when the enable signal has a specific value.

10. The driver circuit according to claim 9, wherein said control device sets said driver into a state with the power being higher than normal when the signal to be output by said driver is changeable.

11. The driver circuit according to claim 10, wherein said driver is set into the state with the power being higher than normal before the value of the signal to be output by said driver could begin to change.

12. The driver circuit according to claim 10, wherein the driver is set into the state with the power being higher than normal precisely when the value of the signal to be output by said driver could begin to change.

13. The driver circuit according to claim 10, wherein the driver is set into the state with the power being higher than normal precisely when the value of the signal to be output by said driver begins to change.

14. The driver circuit according to claim 10, wherein said driver is set to the state with the power being higher than normal after the value of the signal to be output by said driver could begin to change.

15. The driver circuit according to claim 10, wherein said driver is set to the state with the power being higher than normal after the value of the signal to be output by said driver begins to change.

16. The driver circuit according to claim 10, wherein said control device drives said driver by increasing the power of said driver stepwise.

17. The driver circuit according to claims 10, wherein said control device resets the state of the driver to a low power when the value of the signal to be output by said driver does not change following said driver being set to the state with the power being higher than normal.

18. The driver circuit according to claim 17, wherein said driver is reset into the state with the low power after the value of the signal to be output by said driver could have been completely changed.

19. The driver circuit according to claim 17, wherein said driver is reset into the state with the low power after the value of the signal to be output by said driver has been completely changed.

20. The driver circuit according to claim 17, wherein said driver is reset into the state with the low power exactly when the value of the signal to be output by said driver could have been completely changed.

21. The driver circuit according to claim 17, wherein said driver is reset into the state with the low power exactly when the value of the signal to be output by said driver has been completely changed.

22. The driver circuit according to claim 16, wherein said driver is reset into the state with the low power before the value of the signal to be output by said driver could have been completely changed.

23. The driver circuit according to claim 17, wherein said control device drives said driver by reducing the power of said driver stepwise in successive steps.

24. The driver circuit according to claim 1, wherein said control device maintains a low power in said driver when the signal to be output by said driver has an unchanging value.
